(19) United States
(12) Patent Application Publication
(10) Pub. No.: US 2024/0235426 A1
(43) Pub. Date: Jul. 11, 2024

(54) INVERTER-BASED COMPARATOR

(71) Applicants: NCKU Research and Development Foundation, Tainan City (TW); Himax Technologies Limited, Tainan City (TW)

(72) Inventors: Philex Ming-Yan Fan, Tainan City (TW); Yi-Fu Chen, Tainan City (TW); Bo-Rui Chen, Tainan City (TW)

(21) Appl. No.: 18/095,399

(22) Filed: Jan. 10, 2023

(51) Int. Cl. H02M 7/5387; H02M 1/00; H03K 5/24

(52) U.S. Cl. CPC H02M 7/53873; H02M 1/0032; H03K 5/2472

(57) ABSTRACT

An inverter-based comparator, powered between a first supply voltage and a second supply voltage being lower than the first supply voltage, includes a first inverter branch composed of at least one first P-type transistor and at least one first N-type transistor; and a second inverter branch composed of at least one second P-type transistor, at least one second N-type transistor and at least two tuning switches. The first inverter branch and the second inverter branch are configured to compare an input voltage with an internal trigger point, thereby generating a compare voltage at an interconnected node. One of the at least two tuning switches is controlled to isolate the first supply voltage and another is controlled to isolate the second supply voltage to compensate for trigger point shifting.

### BACKGROUND OF THE INVENTION

### 1. Field of the Invention

The present invention generally relates to a comparator, and more particularly to an inverter-based comparator.

### 2. Description of Related Art

Power management integrated circuit (PMIC) is designed to controllably switch a system to a low-power state when inactive, in order to obtain high power conversion efficiency in static operating mode, thereby substantially extending the battery lifetime, for example, in a low power consumption system such as Internet of things (IOT).

Conventional power management ICs use a comparator or an error amplifier for monitoring the output voltage to ensure a stable output voltage and proper load performance. Accordingly, the power management ICs demand always-on comparator or error amplifier, which nonetheless consumes non-negligible power, reduces power conversion efficiency and increases quiescent power, thereby resulting in reduced battery lifetime.

Moreover, the comparator adopted in the conventional power management ICs makes comparison by comparing the input voltage with a reference voltage, which is externally generated by a reference voltage generating circuit that consumes extra power and circuit area.

A need has thus arisen to propose a novel low-power comparator adaptable to low-power power management systems.

### SUMMARY OF THE INVENTION

In view of the foregoing, it is an object of the embodiment of the present invention to provide an inverter-based comparator with a cascoded inverter capable of substantially reducing power consumption and tuning a trigger point thereof.

According to one embodiment, an inverter-based comparator, powered between a first supply voltage and a second supply voltage being lower than the first supply voltage, includes a first inverter branch and a second inverter branch. The first inverter branch is composed of at least one first P-type transistor and at least one first N-type transistor. The second inverter branch is composed of at least one second P-type transistor, at least one second N-type transistor and at least two tuning switches. The first inverter branch and the second inverter branch are configured to compare an input voltage with an internal trigger point, thereby generating a compare voltage at an interconnected node. One of the at least two tuning switches is controlled to isolate the first supply voltage and another is controlled to isolate the second supply voltage to compensate for trigger point shifting.

### BRIEF DESCRIPTION OF THE DRAWINGS

FIG. 1 shows a block diagram illustrating an inverter-based comparator adaptable to low-power power management systems according to one embodiment of the present invention;

FIG. 2 shows a circuit diagram exemplifying the inverter-based comparator of FIG. 1;

FIG. 3 shows a detailed circuit diagram illustrating the inverter of FIG. 2 according to one embodiment of the present invention; and

FIG. 4 shows a circuit diagram illustrating the first inverter branch of FIG. 3 according to another embodiment of the present invention.

### DETAILED DESCRIPTION OF THE INVENTION

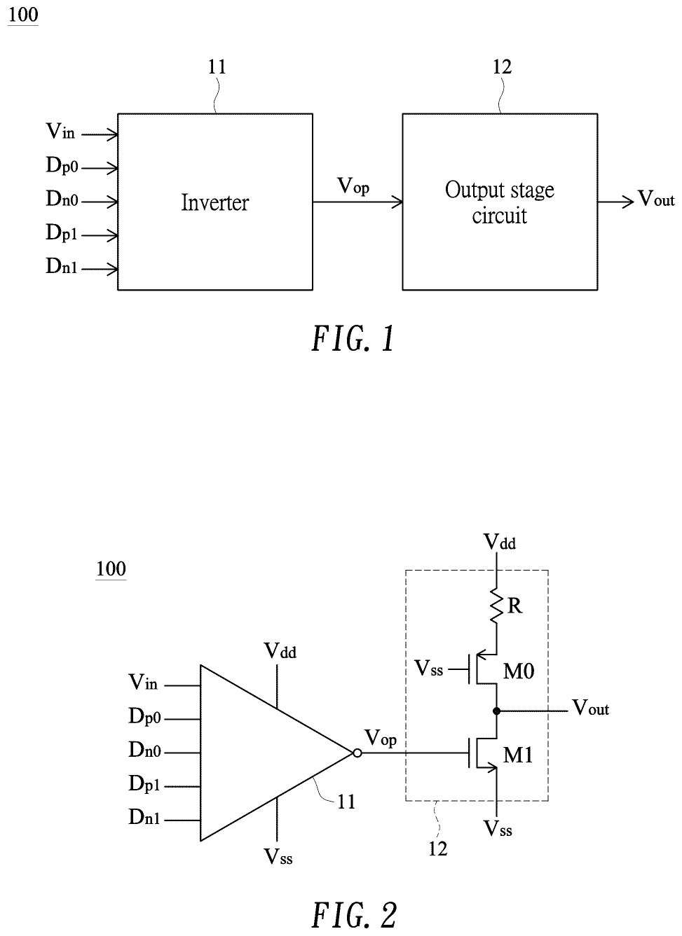

FIG. 1 shows a block diagram illustrating an inverter-based comparator 100 adaptable to low-power power management systems according to one embodiment of the present invention, and FIG. 2 shows a circuit diagram exemplifying the inverter-based comparator 100 of FIG. 1.

In the embodiment, the inverter-based comparator 100 may include an inverter 11 coupled to receive an input voltage Vᵢₙ and configured to compare the input voltage Vᵢₙ with an (internal) trigger point that is internally determined according to the inverter 11 itself, thereby generating a compare voltage Vₒₚ indicating comparison result. As the inverter 11 of the inverter-based comparator 100 makes comparison by comparing the input voltage Vᵢₙ with the internally generated trigger point, instead of an externally provided reference voltage, the inverter-based comparator 100 can substantially reduce power consumption and circuit area. In one embodiment, the inverter 11 is preferably a cascoded inverter, which adopts a cascode structure acquiring more transistor channel length, and current leakage when the input voltage Vᵢₙ is near the trigger point can be greatly reduced, thereby further reducing overall power consumption.

According to one aspect of the embodiment, the trigger point of the inverter 11 may be tuned (or adjusted) by at least one (e.g., digital) tuning signal (Dₙ₀-Dₙ₁ and Dₚ₀-Dₚ₁ as exemplified in FIG. 1 and FIG. 2) that is externally provided, in order to compensate for trigger point shifting due to process variation.

The inverter-based comparator 100 of the embodiment may include an output stage circuit 12 coupled to receive the compare voltage Vₒₚ and configured to ensure a state for the compare voltage Vₒₚ, thereby generating an output voltage Vₒᵤₜ at an output node (of the inverter-based comparator 100).

Specifically, the output stage circuit 12 may include a resistor R, a P-type transistor (e.g., P-type metal-oxide-semiconductor (PMOS) transistor) M0 and an N-type transistor (e.g., N-type metal-oxide-semiconductor (NMOS) transistor) M1, which are connected in series in an order from a first supply voltage (e.g., positive supply voltage V_{dd}) to a second supply voltage (e.g., negative supply voltage Vₛₛ) being lower than the first supply voltage, with a gate of the PMOS transistor M0 coupled to the second supply voltage Vₛₛ, a gate of the NMOS transistor M1 coupled to the compare voltage Vₒₚ, and drains of the PMOS transistor M0 and the NMOS transistor M1 connected at the output node (of the inverter-based comparator 100) for providing the output voltage Vₒᵤₜ.

In operation, when a gate-to-source voltage of the NMOS transistor M1 is greater than a corresponding threshold voltage, the NMOS transistor M1 is turned on and the output voltage Vₒᵤₜ is pulled down to the second supply voltage Vₛₛ, otherwise the NMOS transistor M1 is turned off and the output voltage Vₒᵤₜ is pulled up to the first supply voltage V_{dd} via the resistor R, thereby ensuring that the output voltage Vₒᵤₜ represents the state of the compare voltage Vₒₚ.

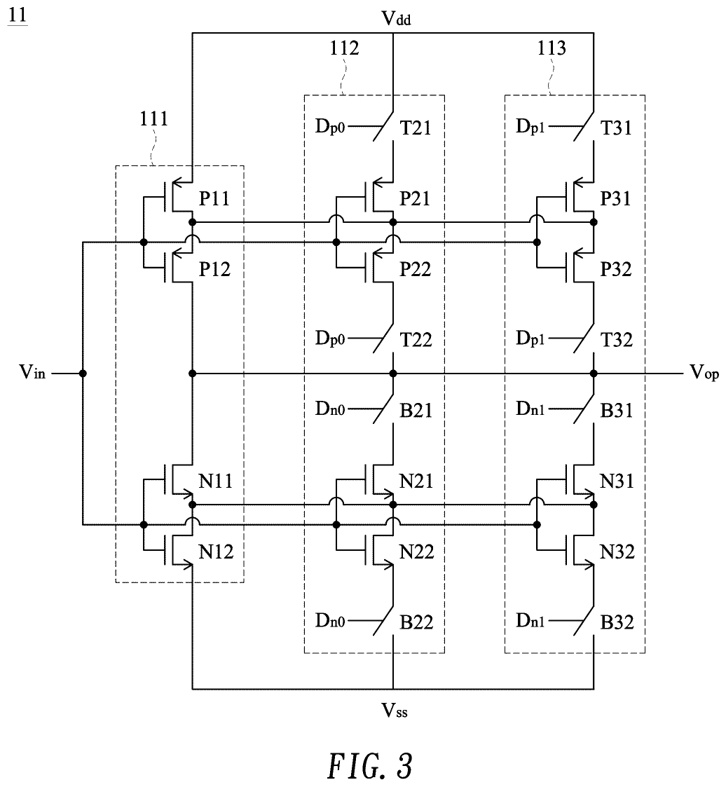

FIG. 3 shows a detailed circuit diagram illustrating the inverter (preferably a cascoded inverter) 11 of FIG. 2 according to one embodiment of the present invention.

Specifically, the cascoded inverter 11 of the embodiment may include a first inverter branch 111 composed of series-connected first PMOS transistors P11-P12 and series-connected first NMOS transistors N11-N12, which are electrically connected in series in the order from the first supply voltage V_{dd} to the second supply voltage Vₛₛ. Gates of the series-connected first PMOS transistors P11-P12 and the series-connected first NMOS transistors N11-N12 are coupled to the input voltage Vᵢₙ, and an interconnected node electrically coupled between the series-connected first PMOS transistors P11-P12 and the series-connected first NMOS transistors N11-N12 provides the compare voltage Vₒₚ. Alternatively, for a non-cascode embodiment, the first inverter branch 111 may be composed of a first PMOS transistor P11 and a first NMOS transistor N11, which are electrically connected in series in the order from the first supply voltage V_{dd} to the second supply voltage Vₛₛ.

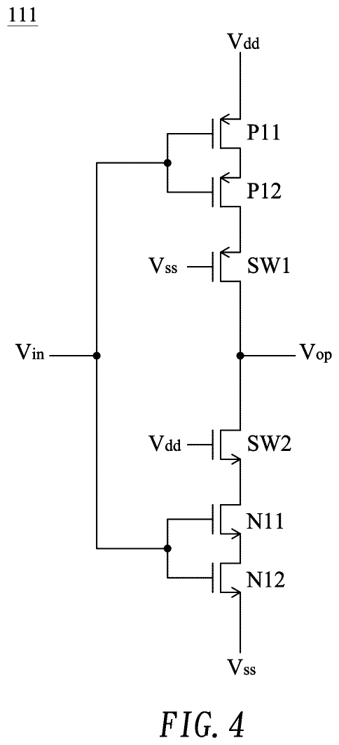

FIG. 4 shows a circuit diagram illustrating the first inverter branch 111 of FIG. 3 according to another embodiment of the present invention. Specifically, the first inverter branch 111 may further include a first switch SW1 (e.g., PMOS transistor) connected between the series-connected first PMOS transistors P11-P12 and the interconnected node Vₒₚ, and a second switch SW2 (e.g., NMOS transistor) connected between the series-connected first NMOS transistors N11-N12 and the interconnected node Vₒₚ. The gate of the first switch SW1 may, for example, be coupled to the second supply voltage Vₛₛ, and the gate of the second switch SW2 may, for example, be coupled to the first supply voltage V_{dd} as exemplified in FIG. 4.

Referring back to FIG. 3, the cascoded inverter 11 of the embodiment may include a second inverter branch 112 composed of series-connected second PMOS transistors P21-P22 and series-connected second NMOS transistors N21-N22, which are electrically connected in series in the order from the first supply voltage V_{dd} to the second supply voltage Vₛₛ. Gates of the series-connected second PMOS transistors P21-P22 and the series-connected second NMOS transistors N21-N22 are coupled to the input voltage Vᵢₙ, and the series-connected second PMOS transistors P21-P22 and the series-connected second NMOS transistors N21-N22 are electrically connected at the interconnected node that provides the compare voltage Vₒₚ. Alternatively, for a non-cascode embodiment, the second inverter branch 112 may be composed of a second PMOS transistor P21 and a second NMOS transistor N21, which are electrically connected in series in the order from the first supply voltage V_{dd} to the second supply voltage Vₛₛ. Moreover, the first switch SW1 and the second switch SW2 as illustrated in FIG. 4 may be adopted in the second inverter branch 112.

According to one aspect of the embodiment, the second inverter branch 112 may further include at least two tuning switches controlled by at least one tuning signal, and configured to isolate the first supply voltage V_{dd} and the second supply voltage Vₛₛ respectively. Each tuning switch may be composed of one MOS transistor, or be composed of two MOS transistors connected in parallel to act as a transmission gate. In one embodiment, the at least two tuning switches may include a top switch (controlled by a first tuning signal Dₚ₀) connected between the first supply voltage V_{dd} and the series-connected second PMOS transistors P21-P22 as denoted by T21, or connected between the series-connected second PMOS transistors P21-P22 and the interconnected node Vₒₚ as denoted by T22; and include a bottom switch (controlled by a second tuning signal Dₙ₀) connected between the interconnected node Vₒₚ and the series-connected second NMOS transistors N21-N22 as denoted by B21, or connected between the series-connected second NMOS transistors N21-N22 and the second supply voltage Vₛₛ as denoted by B22. In an alternative embodiment, the at least two tuning switches may include two top switches T21 and T22, and include two bottom switches B21 and B22.

Similarly, the cascoded inverter 11 of the embodiment may optionally include an third inverter branch 113 composed of series-connected third PMOS transistors P31-P32 and series-connected third NMOS transistors N31-N32, which are electrically connected in series in the order from the first supply voltage V_{dd} to the second supply voltage Vₛₛ. Gates of the series-connected third PMOS transistors P31-P32 and the series-connected third NMOS transistors N31-N32 are coupled to the input voltage Vᵢₙ, and the series-connected third PMOS transistors P31-P32 and the series-connected third NMOS transistors N31-N32 are electrically connected at the interconnected node that provides the compare voltage Vₒₚ. Alternatively, for a non-cascode embodiment, the third inverter branch 113 may be composed of a third PMOS transistor P31 and a third NMOS transistor N31, which are electrically connected in series in the order from the first supply voltage V_{dd} to the second supply voltage Vₛₛ. Moreover, the first switch SW1 and the second switch SW2 as illustrated in FIG. 4 may be adopted in the third inverter branch 113. It is appreciated that, in another embodiment, the third inverter branch 113 may be omitted or a fourth inverter branch or branches like the second/third inverter branch 112/113 may be further included.

According to the aspect of the embodiment, the third inverter branch 113 may further include at least two tuning switches controlled by at least one tuning signal, and configured to isolate the first supply voltage V_{dd} and the second supply voltage Vₛₛ, respectively. Each tuning switch may be composed of one MOS transistor, or be composed of two MOS transistors connected in parallel to act as a transmission gate. In one embodiment, the at least two tuning switches may include a top switch (controlled by a third tuning signal Dₚ₁) connected between the first supply voltage V_{dd} and the series-connected third PMOS transistors P31-P32 as denoted by T31, or connected between the series-connected third PMOS transistors P31-P32 and the interconnected node Vₒₚ as denoted by T32; and include a bottom switch (controlled by a fourth tuning signal Dₙ₁) connected between the interconnected node Vₒₚ and the series-connected third NMOS transistors N31-N32 as denoted by B31, or connected between the series-connected third NMOS transistors N31-N32 and the second supply voltage Vₛₛ as denoted by B32. In an alternative embodiment, the at least two tuning switches may include two top switches T31 and T32, and include two bottom switches B31 and B32. Interlinked nodes of the series-connected first PMOS transistors P11-P12, the series-connected second PMOS transistors P21-P22 and the series-connected third PMOS transistors P31-P32 may be connected together, and interlinked node of the series-connected first NMOS transistors N11-N12, the series-connected second NMOS transistors N21-N22 and the series-connected third NMOS transistors N31-N32 may be connected together.

Although specific embodiments have been illustrated and described, it will be appreciated by those skilled in the art that various modifications may be made without departing from the scope of the present invention, which is intended to be limited solely by the appended claims.

What is claimed is:

1. An inverter-based comparator powered between a first supply voltage and a second supply voltage being lower than the first supply voltage, comprising:
a first inverter branch composed of at least one first P-type transistor and at least one first N-type transistor; and
a second inverter branch composed of at least one second P-type transistor, at least one second N-type transistor and at least two tuning switches;
wherein the first inverter branch and the second inverter branch are configured to compare an input voltage with an internal trigger point, thereby generating a compare voltage at an interconnected node; and
one of the at least two tuning switches is controlled to isolate the first supply voltage and another is controlled to isolate the second supply voltage to compensate for trigger point shifting.

2. The comparator of claim 1, wherein the second inverter branch is coupled to receive at least one tuning signal for controlling the at least two tuning switches.

3. The comparator of claim 1, wherein the at least one first P-type transistor and the at least one first N-type transistor are electrically connected in series in an order from a first supply voltage to a second supply voltage being lower than the first supply voltage, gates of the at least one first P-type transistor and the at least one first N-type transistor are coupled to the input voltage, and the interconnected node electrically coupled between the at least one first P-type transistor and the at least one first N-type transistor provides the compare voltage.

4. The comparator of claim 1, wherein the at least one second P-type transistor and the at least one second N-type transistor are electrically connected in series in the order from the first supply voltage to the second supply voltage, gates of the at least one second P-type transistor and the at least one second N-type transistor are coupled to the input voltage, and the at least one second P-type transistor and the at least one second N-type transistor are electrically coupled at the interconnected node.

5. The comparator of claim 1, wherein the at least two tuning switches comprise:
a top switch connected between the first supply voltage and the at least one second P-type transistor or between the interconnected node and the at least one second P-type transistor; and
a bottom switch connected between the second supply voltage and the at least one second N-type transistor or between the interconnected node and the at least one second N-type transistor.

6. The comparator of claim 1, wherein the at least two tuning switches comprise:
two top switches respectively connected between the first supply voltage and the at least one second P-type transistor and between the interconnected node and the at least one second P-type transistor; and
two bottom switches respectively connected between the second supply voltage and the at least one second N-type transistor and between the interconnected node and the at least one second N-type transistor.

7. The comparator of claim 1, wherein the at least one first P-type transistor comprises series-connected first P-type transistors, the at least one first N-type transistor comprises series-connected first N-type transistors, the at least one second P-type transistor comprises series-connected second P-type transistors, the at least one second N-type transistor comprises series-connected second N-type transistors, the at least one third P-type transistor comprises series-connected third P-type transistors, or the at least one third N-type transistor comprises series-connected third N-type transistors.

8. The comparator of claim 1, further comprising:
an output stage circuit coupled to receive the compare voltage and configured to ensure a state for the compare voltage, thereby generating an output voltage at an output node.

9. The comparator of claim 8, wherein the output stage circuit comprises a resistor, a P-type transistor and an N-type transistor, which are connected in series in an order from a first supply voltage to a second supply voltage being lower than the first supply voltage, with a gate of the P-type transistor coupled to the second supply voltage, a gate of the N-type transistor coupled to the compare voltage, and drains of the P-type transistor and the N-type transistor connected at the output node.
